(19) United States
(12) Patent Application Publication
(10) Pub. No.: US 2023/0209721 A1
(43) Pub. Date: Jun. 29, 2023

(54) PLATING METHOD AND METHOD OF MANUFACTURING PRINTED CIRCUIT BOARD

(71) Applicant: Nitto Denko Corporation, Osaka (JP)

(72) Inventors: Shotaro NAGAOKA, Osaka (JP); Yuu SUGIMOTO, Osaka (JP)

(21) Appl. No.: 18/082,894

(22) Filed: Dec. 16, 2022

(30) Foreign Application Priority Data
Dec. 27, 2021 (JP) 2021-212394

(51) Int. Cl. H05K 3/18; H05K 3/26

(52) U.S. Cl. CPC H05K 3/188; H05K 3/26; H05K 2203/0723; H05K 2203/0789; H05K 2203/1484

(57) ABSTRACT

In a plating method, a laminate made of stainless steel, and copper or a copper alloy is prepared. Plating underlayers made of nickel are formed on a first plated portion provided at the stainless steel and a second plated portion provided at the copper or the copper alloy at the same time with use of a hydrochloric acid electrolytic solution.

### BACKGROUND

### Technical Field

The present invention relates to a plating method and a method of manufacturing a printed circuit board.

### Description of Related Art

A laminate in which different types of metals are laminated may be used as an electronic product. For example, in a printed circuit board used in a drive device such as a hard disc drive device, a stainless steel plate and a conductor layer made of copper or a copper alloy are formed with an insulating layer provided therebetween. A plating process is executed on predetermined portions of the stainless steel plate and the conductor layer, so that a printed circuit board is manufactured (see JP 2014-210959 A, for example.).

It is preferable that the plating process is executed on the stainless steel plate and the conductor layer at the same time. However, a passive film is formed on the surface of the stainless steel plate. Therefore, it is not easy to execute the plating process on the stainless steel plate and the conductor layer at the same time.

In JP 2014-210959 A, before the plating process for the stainless steel plate, a voltage is applied between the stainless steel plate and an electrode such that the stainless steel plate serves as an anode and the electrode in a plating layer serves as a cathode. In this case, the passive film formed on a plated portion is dissolved and removed by reduction reaction. Such a process of removing the passive film (a reverse electrolytic process) is executed on the stainless steel plate in advance, so that the plating process is executed on the stainless steel plate and the conductor layer at the same time.

### SUMMARY

In the plating method of JP 2014-210959 A, since the reverse electrolytic process is executed on a member to be plated, the number of steps in the process increases, and the number of components of the plating apparatus increases. As a result, the cost required for the plating process increases.

An object of the present invention is to provide a plating method and a method of manufacturing a printed circuit board that enable reduction of a cost required for a plating process.

Generally, in a case in which the plating process is executed on stainless steel, an electrolytic solution (a woods bath) including nickel chloride as a main component is used to remove a passive film on a surface. However, because a woods bath is highly corrosive, stainless steel may be damaged. Therefore, J P 2014-210595 A suggests that an electrolytic solution including a highly corrosive component such as chlorine is not to be used.

It has been considered that, in a case in which a woods bath is used for a plating process for copper or a copper alloy (hereinafter simply referred to as copper), copper is more damaged than stainless steel. Further, since a passive film is hardly formed on the surface of copper, it is not necessary to use a woods bath in a plating process. Therefore, in a case in which a plating process is executed on copper, an electrolytic solution (a watts bath) including nickel sulfate as a main component has been used conventionally.

Also in the plating method of JP 2014-210959 A, an electrolytic solution including nickel sulfate as a main component is used for a plating process for a stainless steel plate and copper. However, in the plating method of JP 2014-210595 A, it is required to execute a reverse electrolytic process on the stainless steel plate in advance in order to remove a passive film on the surface of the stainless steel plate.

As a result of having repeated experiments and studies using various electrolytic solutions without conventional technical bias, the inventors of the present invention have found that stainless steel and copper are not significantly damaged even in a case in which a woods bath is used as an electrolytic solution. The inventors of the present application have conceived the following configuration based on this finding.

(1) A plating method according to one aspect of the present invention includes preparing a laminate made of stainless steel, and copper or a copper alloy, and forming plating underlayers made of nickel on a first plated portion provided at the stainless steel and a second plated portion provided at the copper or the copper alloy at a same time using a hydrochloric acid electrolytic solution.

With this plating method, it is possible to form a plating underlayer made of nickel on the first plated portion made of stainless steel and the second plated portion made of copper or a copper alloy at the same time by using a hydrochloric acid electrolytic solution. In this case, an increase in number of steps required for the plating process is prevented. Therefore, the cost required for the plating process can be reduced.

(2) The forming plating underlayers may include forming plating underlayers on the first plated portion and the second plated portion under a same plating condition. In this case, the plating process can be executed on the first plated portion and the second plated portion in the same plating tank. Therefore, the cost required for the plating process can be reduced more sufficiently.

(3) The plating condition may include a current density or a voltage. This more sufficiently facilitates formation of the plating underlayers on the first plated portion and the second plated portion at the same time.

(4) The forming plating underlayers may include applying a voltage to each of the first plated portion and the second plated portion using a common electrode. In this case, an increase in number of components required for the plating process is prevented. Therefore, the cost required for the plating process can be reduced more sufficiently.

(5) A concentration of hydrochloric acid in an electrolytic solution may be not less than 60 ml/L. In this case, the adhesion between the first plated portion and the second plated portion, and nickel is improved. This more sufficiently facilitates formation of the plating underlayers on the first plated portion and the second plated portion at the same time.

(6) The plating method may further include forming plating underlayers made of nickel on plating underlayers formed on the first plated portion and the second plated portion. In this case, plating underlayers having a sufficiently large thickness can be formed on the first plated portion and the second plated portion.

(7) The plating method may further include forming plating layers made of gold (Au) on plating underlayers formed on the first plated portion and the second plated portion. In this case, corrosion resistance of the surface of the first plated portion and the second plated portion can be improved, and wettability of a solder can be improved.

(8) The laminate may be a printed circuit board in which the stainless steel and a conductor layer made of copper or a copper alloy are laminated, the first plate portion may be a first terminal portion provided at the stainless steel, and the second plated portion may be a second terminal portion provided at the conductor layer. In this case, in the printed circuit board, the plating underlayers made of nickel can be formed on the first terminal portion made of stainless steel and the second terminal portion made of copper or a copper alloy at the same time.

(9) A method of manufacturing a printed circuit board according to another aspect of the present invention includes preparing a laminate including stainless steel and a conductor layer made of copper or a copper alloy, forming a first connection terminal and a second connection terminal at the laminate at a same time, forming the first connection terminal includes forming a plating underlayer made of nickel on a first terminal portion provided at the stainless steel using a hydrochloric acid electrolytic solution, and forming the second connection terminal includes forming a plating underlayer made of nickel on a second terminal portion provided at the conductor layer using a hydrochloric acid electrolytic solution.

With this method of manufacturing the printed circuit board, because a hydrochloric acid electrolytic solution is used, plating underlayers made of nickel are formed on the first terminal portion made of stainless steel and the second terminal portion made of copper or a copper alloy at the same time. Thus, the first connection terminal and the second connection terminal are formed at the same time. In this case, an increase in number of steps required for manufacturing of the printed circuit board is prevented. Therefore, the cost required for manufacturing of the printed circuit board can be reduced.

(10) The forming a first connection terminal and a second connection terminal may include forming the first connection terminal and the second connection terminal under a same plating condition. In this case, the plating process can be executed on the first terminal portion and the second terminal portion in the same plating tank. Therefore, the cost required for manufacturing of the printed circuit board can be reduced.

(11) The plating condition may include a current density or a voltage. In this case, formation of the plating underlayers on the first terminal portion and the second terminal portion at the same time is facilitated more sufficiently.

(12) The forming a first connection terminal and a second connection terminal may include applying a voltage to each of the first terminal portion and the second terminal portion using a common electrode. In this case, an increase in number of components required for manufacturing of the printed circuit board is prevented. Therefore, the cost required for manufacturing of the printed circuit board can be reduced.

(13) A concentration of hydrochloric acid in an electrolytic solution may be not less than 60 ml/L. In this case, the adhesion between the first plated portion and the second plated portion, and nickel is improved. This more sufficiently facilitates formation of the plating underlayers on the first plated portion and the second plated portion at the same time.

(14) The forming the first connection terminal further may include forming a plating underlayer made of nickel on a plating underlayer formed on the first terminal portion, and the forming the second connection terminal may further include forming a plating underlayer made of nickel on a plating underlayer formed on the second terminal portion. In this case, plating underlayers having a sufficiently large thickness can be formed on the first terminal portion and the second terminal portion.

(15) The forming the first connection terminal may include forming a plating layer made of gold (Au) on a plating underlayer formed on the first terminal portion, and the forming the second connection terminal may further include forming a plating layer made of gold (Au) on a plating underlayer formed on the second terminal portion. In this case, corrosion resistance of the surface of the first connection terminal and the second connection terminal can be improved, and wettability of a solder can be improved.

Other features, elements, characteristics, and advantages of the present disclosure will become more apparent from the following description of preferred embodiments of the present disclosure with reference to the attached drawings.

### BRIEF DESCRIPTION OF THE DRAWING

FIG. 1 is a schematic diagram showing the configuration of a plating apparatus that is used when a plating method according to an embodiment of the present invention is performed;

FIG. 2 shows SEM photographs of the appearance of a laminate in an inventive example;

FIG. 3 shows SEM photographs of the appearance of the laminate in a comparative example;

FIG. 4 is a plan view of a suspension board;

FIG. 5 is a cross sectional view of the suspension board of FIG. 4 taken along the line A-A;

FIG. 6 is an enlarged plan view of a tongue as viewed from one side;

FIG. 7 is an enlarged plan view of the tongue as viewed from the other side;

FIG. 8 is a cross sectional view of the tongue of each of FIGS. 6 and 7 taken along the line B-B;

FIG. 9 is a cross sectional view of the tongue of each of FIGS. 6 and 7 taken along the line C-C;

FIG. 10 is a block diagram showing the configuration of a plating system that is used in a method of manufacturing a suspension board;

FIG. 11 is a cross sectional view for explaining the step in the method of the manufacturing the suspension board;

FIG. 12 is a cross sectional view for explaining the step in the method of the manufacturing the suspension board;

FIG. 13 is a cross sectional view for explaining the step in the method of the manufacturing the suspension board;

FIG. 14 is a cross sectional view for explaining the step in the method of the manufacturing the suspension board; and

FIG. 15 is a cross sectional view for explaining the step in the method of the manufacturing the suspension board.

### DETAILED DESCRIPTION

### [1] Plating Apparatus

(1) Configuration of Plating Apparatus

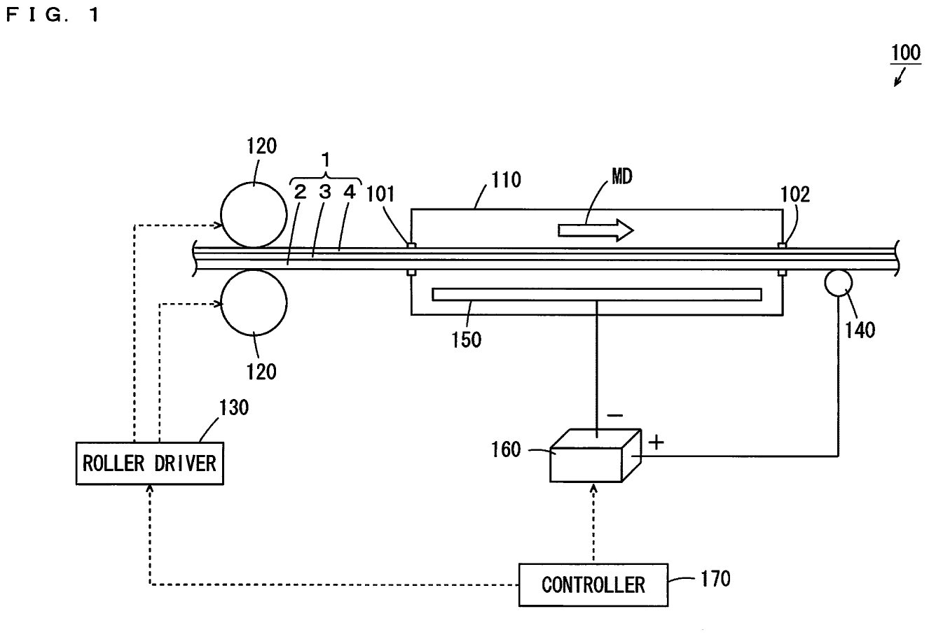

A plating method and a method of manufacturing a printed circuit board according to embodiments of the present invention will be described below with reference to the drawings. FIG. 1 is a schematic diagram showing the configuration of a plating apparatus that is used when a plating method according to an embodiment of the present invention is performed. As shown in FIG. 1, the plating apparatus 100 includes a plating tank 110, a pair of transport rollers 120, a roller driver 130, a power feed roller 140, an electrode 150, a rectifier 160 and a controller 170. The roller driver 130 and the rectifier 160 are controlled by the controller 170.

In the present embodiment, a member to be plated is a laminate 1 having an elongated shape. The laminate 1 includes a stainless steel plate 2, an insulating layer 3, and a conductor layer 4 made of copper or a copper alloy. The insulating layer 3 includes polyimide, for example. The stainless steel plate 2 is formed on one surface of the insulating layer 3. The conductor layer 4 is formed on the other surface of the insulating layer 3.

On the surface of each of the stainless steel plate 2 and the conductor layer 4, a plurality of portions on which a plating underlayer is to be formed by the plating apparatus 100 are provided. Hereinafter, a portion of the laminate 1 on which a plating underlayer is to be formed is referred to as a plated portion. In particular, a portion of the surface of the stainless steel plate 2 on which a plating underlayer is to be formed is referred to as a first plated portion, and a portion of the surface of the conductor layer 4 on which a plating underlayer is to be formed is referred to as a second plated portion.

An electrolytic solution is stored in the plating tank 110. The electrolytic solution includes nickel chloride hexahydrate (hereinafter simply referred to as nickel chloride) and hydrochloric acid as main components. The concentration of nickel chloride in the electrolytic solution is preferably not lower than 100 g/L and lower than 360 g/L. When the concentration of nickel chloride is not lower than 100 g/L, current efficiency is improved. Further, when the concentration of nickel chloride is lower than 360 g/L, the thickness of a plating underlayer is prevented from being non-uniform. Further, an increase in cost is suppressed.

The concentration of hydrochloric acid in the electrolytic solution is preferably not lower than 60 ml/L and lower than 280 ml/L. When the concentration of hydrochloric acid is not lower than 60 ml/L, current efficiency is improved. Further, the adhesion between each of the first and second plated portions, and nickel is improved. This more sufficiently facilitates formation of the plating underlayers on the first plated portion and the second plated portion at the same time. When the concentration of hydrochloric acid is lower than 280 ml/L, degradation of deposition efficiency of nickel can be prevented.

The temperature of the electrolytic solution is not lower than 15° C. and lower than 40° C., for example, and is preferably 25° C. When the temperature of the electrolytic solution is lower than 40° C., corrosion of metal due to generation of a hydrogen chloride gas can be prevented.

The laminate 1 is held by the pair of transport rollers 120. When the pair of transport rollers 120 are rotationally driven by the roller driver 130, the laminate 1 is transported. The plating tank 110 is provided with a carry-in port 101 and a carry-out port 102. The laminate 1 is carried into the plating tank 110 through the carry-in port 101 and carried out from the plating tank 110 through the carry-out port 102. In this case, in the plating tank 110, the laminate 1 is transported in the direction of the arrow MD (hereinafter referred to as a transport direction) in the electrolytic solution. Thus, the plating apparatus 100 executes a plating process on the laminate 1 using a roll-to-roll method.

When the speed at which the laminate 1 is transported is controlled, a plating period of time is adjusted. While the plating period of time is not less than 10 seconds and not more than 300 seconds, for example, the embodiment is not limited to this. The plating period of time is suitably set according to the thickness of a plating underlayer to be formed. The upper limit of the plating period of time is preferably set such that the first and second plated portions are not damaged.

The power feed roller 140 is arranged outside of the plating tank 110. The power feed roller 140 may be arranged at a position farther upstream than the carry-in port 101 or may be arranged at a position farther downstream than the carry-out port 102. Further, the power feed roller 140 comes into contact with a portion of the stainless steel plate 2 or the conductor layer 4 of the laminate 1. The power feed roller 140 is provided to be rotatable so as not to cause friction between the power feed roller 140 and the laminate 1. The power feed roller 140 may be rotationally driven by a motor or the like such that a force is applied from the power feed roller 140 to the laminate 1 in the transport direction.

The electrode 150 is arranged in the plating tank 110 so as to be opposite to the stainless steel plate 2 or the conductor layer 4 of the laminate 1. As a material of the electrode 150, stainless steel, nickel or platinum is used, for example. The power feed roller 140 is connected to a positive electrode of the rectifier 160, and the electrode 150 is connected to a negative electrode of the rectifier 160. The rectifier 160 applies a voltage between the laminate 1 that comes into contact with the power feed roller 140 and the electrode 150. In this case, the laminate 1 serves as a cathode, and the electrode 150 serves as an anode.

The current density in the electrolytic solution caused by the rectifier 160 (the current density between the electrode 150 and the laminate 1) is preferably not lower than 2 A/dm² and lower than 50 A/dm². When the current density in the electrolytic solution caused by the rectifier 160 is not less than 2 A/dm², the adhesion between a plated portion and a plating underlayer is improved. Further, when the current density in the electrolytic solution caused by the rectifier 160 is lower than 50 A/dm², a voltage applied between the laminate 1 having high electric resistance and the electrode 150 is prevented from being excessively high.

(2) Plating Method

A method of plating the laminate 1 using the plating apparatus 100 of FIG. 1 will be described. The below-mentioned operation of the plating apparatus 100 is realized when the roller driver 130 and the rectifier 160 are controlled by the controller 170.

The laminate 1 is carried into the plating tank 110 through the carry-in port 101 by the transport roller 120 and transported in the transport direction. When the first plated portion in the stainless steel plate 2 and the second plated portion in the conductor layer 4 are carried into the plating tank 110, a voltage is applied between the first plated portion and the electrode 150 by the rectifier 160, and a voltage is applied between the second plated portion and the electrode 150 by the rectifier 160.

Thus, nickel is deposited on the first and second plated portions at the same time. As a result, plating underlayers made of nickel are formed on the first and second plated portions. Hereinafter, such a process of forming plating underlayers is referred to as an electrolytic plating process. The thickness of a plating underlayer is not less than 0.01 μm and not more than 3.0 μm, for example.

Similarly, the electrolytic plating process is executed on a portion to be plated each time an unprocessed plated portion in the laminate 1 is transported into the plating tank 110. In this manner, after a plating underlayer is formed on a plated portion, a plating underlayer made of nickel may further be formed by electrolytic plating on the plating underlayer in another plating tank (not shown). In this case, a plating underlayer having a sufficiently large thickness can be formed on the plated portion.

Alternatively, after a plating underlayer is formed on a plated portion, a plating layer (hereinafter referred to as a main plating layer) made of gold (Au) may be formed by electrolytic plating on the plating underlayer in another plating tank (not shown). In this case, corrosion resistance of the surface of the plated portion can be improved, and wettability of a solder can be improved. The thickness of the main plating layer is not less than 0.1 μm and not more than 5.0 μm, for example.

(3) Effects

With the plating method according to the present embodiment, it is possible to form plating underlayers made of nickel on the first plated portion made of stainless steel and the second plated portion made of copper or a copper alloy at the same time by using a hydrochloric acid electrolytic solution. In this case, an increase in number of steps required for the plating process is prevented. Therefore, the cost required for the plating process can be reduced.

The plating underlayers are formed on the first plated portion and the second plated portion under the same plating condition. Specifically, the plating underlayers are formed on the first plated portion and the second plated portion at the same current density (that is a voltage). In this case, the plating process can be executed on the first plated portion and the second plated portion in the same plating tank. Therefore, the cost required for the plating process can be reduced more sufficiently. Further, this more sufficiently facilitates formation of the plating underlayers on the first and second plated portions at the same time.

The plating underlayers are formed by application of a voltage to each of the first plated portion and the second plated portion with use of the common electrode 150. In this case, an increase in number of components required for the plating process is prevented. Therefore, the cost required for the plating process can be reduced more sufficiently.

### [2] Inventive Examples

In each of the inventive examples 1 to 4 and the comparative examples 1 to 3, described below, a plating underlayer was formed by the plating apparatus 100 on each of the stainless steel plate 2 and the conductor layer 4 of the laminate 1 under various conditions. The stainless steel plate 2 is made of SUS304.

In the inventive example 1, a copper-foil CF-T49A-DS-HD2-18 (manufactured by FUKUDA METAL FOIL & POWDER Co., LTD.) was used as the conductor layer 4. As a pre-process, the surface of the laminate 1 was degreased with a degreasing liquid, and then soft etching was performed on the surface of the conductor layer 4 of the laminate 1. Further, the laminate 1 on which the soft etching has been performed was sufficiently cleaned with acid. After the pre-process, the electrolytic plating process was executed. In the electrolytic plating process, a woods bath was used as an electrolytic solution. The current density in the electrolytic solution was 2 A/dm², and the temperature of the electrolytic solution was 25° C. The concentration of nickel chloride in the electrolytic solution was 240 g/L, and the concentration of hydrochloric acid was 120 ml/L. A plating period of time was 60 seconds.

In an inventive example 2, the pre-process and the electrolytic plating process were executed similarly to the inventive example 1 except for the following points. In the electrolytic plating process, the current density in an electrolytic solution was 15 A/dm², and the temperature of the electrolytic solution was 30° C. The concentration of nickel chloride in the electrolytic solution was 280 g/L, and the concentration of hydrochloric acid was 140 ml/L. A plating period of time was 30 seconds.

In an inventive example 3, the pre-process and the electrolytic plating process were executed similarly to the inventive example 2 except for the following points. In the electrolytic plating process, the current density in the electrolytic solution was 30 A/dm², and the temperature of the electrolytic solution was 20° C. The concentration of nickel chloride in the electrolytic solution was 200 g/L, and the concentration of hydrochloric acid was 100 ml/L.

In an inventive example 4, the pre-process and the electrolytic plating process were executed similarly to the inventive example 1 except that a copper alloy foil HS1200 (manufactured by JX Nippon Mining & Metals Corporation) was used as the conductor layer 4.

In a comparative example 1, a copper foil CF-T49A-DS-HD2-18 (manufactured by FUKUDA METAL FOIL & POWDER Co., LTD.) was used as the conductor layer 4. After the pre-process was executed similarly to the inventive example 1, the electrolytic plating process was executed. In the electrolytic plating process, a watts bath was used as an electrolytic solution. The current density in the electrolytic solution was 2 A/dm², and the temperature of the electrolytic solution was 55° C. The concentration of nickel chloride in the electrolytic solution was 64 g/L, the concentration of nickel sulfate hexahydrate (hereinafter simply referred to as nickel sulfate) was 260 g/L, and the concentration of boric acid was 33 ml/L. A plating period of time was 60 seconds.

In a comparative example 2, the pre-process and the electrolytic plating process were executed similarly to the comparative example 1 except for the following points. In the electrolytic plating process, the current density in an electrolytic solution was 15 A/dm², and a plating period of time was 30 seconds.

In a comparative example 3, the pre-process and the electrolytic plating process were executed similarly to the comparative example 1 except that a copper alloy foil HS1200 (manufactured by JX Nippon Mining & Metals Corporation) was used as the conductor layer 4.

The adhesion of the plating underlayers formed in the inventive examples 1 to 4 and the comparative Examples 1 to 3 was evaluated by a cross-cut test. Table 1 shows the plating conditions and the evaluation results in regard to the adhesion of the plating underlayers in the inventive examples 1 to 4 and the comparative examples 1 to 3.

TABLE 1

| | INVENTIVE | INVENTIVE | INVENTIVE | INVENTIVE | COMPARATIVE | COMPARATIVE | COMPARATIVE |
|---|---|---|---|---|---|---|---|
| | EXAMPLE | EXAMPLE | EXAMPLE | EXAMPLE | EXAMPLE | EXAMPLE | EXAMPLE |
| | 1 | 2 | 3 | 4 | 1 | 2 | 3 |
| ELECTROLYTIC | WOODS | WOODS | WOODS | WOODS | WATTS | WATTS | WATTS |
| SOLUTION | BATH | BATH | BATH | BATH | BATH | BATH | BATH |
| CONDUCTOR | COPPER | COPPER | COPPER | COPPER | COPPER | COPPER | COPPER |
| LAYER | | | | ALLOY | | | ALLOY |
| CURRENT | 2 | 15 | 30 | 2 | 2 | 15 | 2 |
| DENSITY [A/dm²] | | | | | | | |
| TEMPERATURE | 25 | 30 | 20 | 25 | 55 | 55 | 55 |
| OF | | | | | | | |
| ELECTROLYTIC | | | | | | | |
| SOLUTION [° C.] | | | | | | | |
| CONCENTRATION | 240 | 280 | 200 | 240 | 64 | 64 | 64 |
| OF NICKEL | | | | | | | |
| CHLORIDE[g/L] | | | | | | | |
| CONCENTRATION | 120 | 140 | 100 | 120 | | | |
| OF | | | | | | | |
| HYDROCHLORIC | | | | | | | |
| ACID[m/L] | | | | | | | |
| CONCENTRATION | | | | | 260 | 260 | 260 |
| OF NICKEL | | | | | | | |
| SULFATE[g/L] | | | | | | | |
| CONCENTRATION | | | | | 33 | 33 | 33 |
| OF BORIC ACID | | | | | | | |
| [g/L] | | | | | | | |
| PLATING PERIOD | 60 | 30 | 30 | 80 | 80 | 80 | 80 |
| OF TIME [seconds] | | | | | | | |
| EVALUATION | GOOD | GOOD | GOOD | GOOD | NOT GOOD | NOT GOOD | NOT GOOD |

As shown in Table 1, as a result of the cross-cut test, in each of the inventive examples 1 to 4, the plating underlayer was not stripped away from the stainless steel plate 2 or the conductor layer 4. On the other hand, in each of the comparative examples 1 to 3, although the plating underlayer was not stripped away from the conductor layer 4, the plating underlayer was stripped away from the stainless steel plate 2.

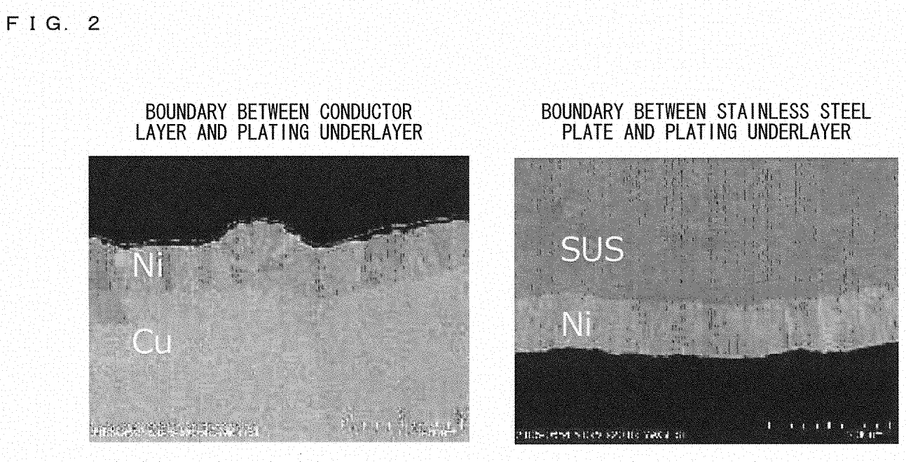

Further, the adhesion of a plating underlayer was evaluated in regard to appearance of a laminate 1. FIG. 2 shows SEM (scanning electron microscope) photographs of the appearance of the laminate 1 in the inventive example. The left SEM photograph of FIG. 2 shows the cross section of the boundary between the conductor layer 4 and the plating underlayer in the inventive example 2. The right SEM photograph of FIG. 2 shows the cross section of the boundary between the stainless steel plate 2 and the plating underlayer in the inventive example 2.

As shown in FIG. 2, in a case in which a woods bath was used as an electrolytic solution, voids were not generated in the boundary between the conductor layer 4 and the plating underlayer or the boundary between the stainless steel plate 2 and the plating underlayer. Thus, it was confirmed that, in a case in which a woods bath was used as an electrolytic solution, adhesion of a plating underlayer was improved.

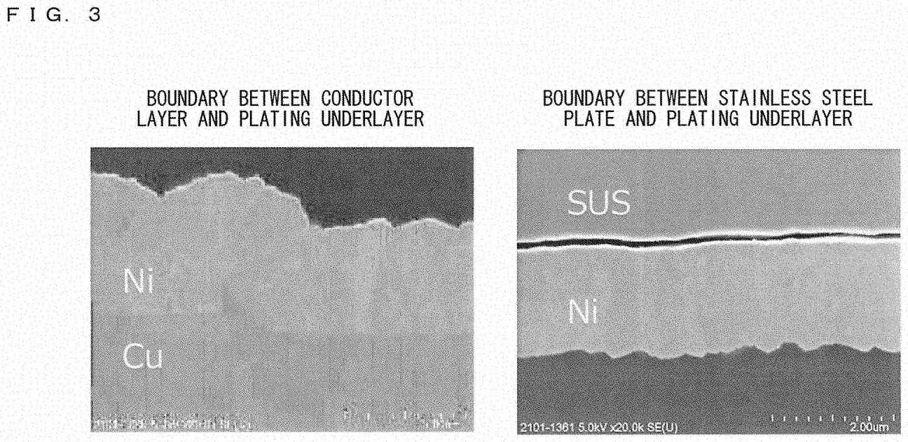

FIG. 3 shows SEM photographs of the appearance of the laminate 1 in the comparative example. The left SEM photograph in FIG. 3 shows the cross section of the boundary between the conductor layer 4 and the plating underlayer in the comparative example 1. The right SEM photograph in FIG. 3 shows the cross section of the boundary between the stainless steel plate 2 and the plating underlayer in the comparative example 1. When the plating underlayer of FIG. 3 is formed, the current density in the electrolytic solution was 4 A/dm², and the plating period of time was 150 seconds.

As shown in FIG. 3, in a case in which a watts bath was used as an electrolytic solution, voids were not generated in the boundary between the conductor layer 4 and the plating underlayer. However, voids were generated in the boundary between the stainless steel plate 2 and the plating underlayer. Thus, it was confirmed that, in a case in which a watts bath was used as an electrolytic solution, adhesion of a plating underlayer was not good.

### [3] Reference Example

(1) Stainless Steel Plate

In the following reference examples 1 to 5, a plating underlayer was formed on a stainless steel plate under various conditions by the plating apparatus 100, and evaluation was conducted. The stainless-steel plate is made of SUS304.

In the reference example 1, after the pre-process was executed similarly to the inventive example 1, the electrolytic plating process was executed. In the electrolytic plating process, a woods bath was used as an electrolytic solution. The current density in the electrolytic solution was 2 A/dm², and the temperature of the electrolytic solution was 25° C. The concentration of nickel chloride in the electrolytic solution was 240 g/L, and the concentration of hydrochloric acid was 120 ml/L. A plating period of time was 60 seconds.

In the reference example 2, the pre-process and the electrolytic plating process were executed similarly to the reference example 1 except for the following points. In the electrolytic plating process, the current density in an electrolytic solution was 15 A/dm², and a plating period of time was 30 seconds.

In the reference example 3, the pre-process and the electrolytic plating process were executed similarly to the reference example 2 except for the following points. In the electrolytic plating process, the current density in an electrolytic solution was 30 A/dm².

In the reference example 4, after the pre-process was executed similarly to the reference example 1, the electrolytic plating process was executed. In the electrolytic plating process, a watts bath was used as an electrolytic solution. The current density in the electrolytic solution was 2 A/dm², and the temperature of the electrolytic solution was 55° C. The concentration of nickel chloride in the electrolytic solution was 64 g/L, the concentration of nickel sulfate was 260 g/L, and the concentration of boric acid was 33 ml/L. A plating period of time was 60 seconds.

In the reference example 5, the pre-process and the electrolytic plating process were executed similarly to the reference example 4 except for the following points. In the electrolytic plating process, the current density in an electrolytic solution was 15 A/dm², and a plating period of time was 30 seconds.

The adhesion of the plating underlayers formed in the reference examples 1 to 5 was evaluated by a cross-cut test. Table 2 shows the plating conditions and the evaluation results in regard to adhesion of the plating underlayers in the reference examples 1 to 5.

TABLE 2

| | REFERENCE | REFERENCE | REFERENCE | REFERENCE | REFERENCE |
|---|---|---|---|---|---|
| | EXAMPLE 1 | EXAMPLE 1 | EXAMPLE 3 | EXAMPLE 4 | EXAMPLE 5 |
| ELECTROLYTIC | WOODS | WOODS | WOODS | WATTS | WATTS |
| SOLUTION | BATH | BATH | BATH | BATH | BATH |
| CURRENT | 2 | 15 | 30 | 2 | 15 |
| DENSITY [A/dm²] | | | | | |
| TEMPERATURE | 25 | 25 | 25 | 55 | 55 |
| OF | | | | | |
| ELECTROLYTIC | | | | | |
| SOLUTION [° C.] | | | | | |
| CONCENTRATION | 240 | 240 | 240 | 64 | 64 |
| OF NICKEL | | | | | |
| CHLORIDE [g/L] | | | | | |
| CONCENTRATION | 120 | 120 | 120 | | |
| OF | | | | | |
| HYDROCHLORIC | | | | | |
| ACID [ml/L] | | | | | |
| CONCENTRATION | | | | 280 | 230 |
| OF NICKEL | | | | | |
| SULFATE [g/L] | | | | | |
| CONCENTRATION | | | | 33 | |
| OF BORIC ACID | | | | | |
| [g/L] | | | | | |
| PLATING PERIOD | 60 | 30 | 30 | 60 | 30 |
| OF TIME [seconds] | | | | | |
| EVALUATION | GOOD | GOOD | GOOD | NOT GOOD | NOT GOOD |

As shown in Table 2, as a result of the cross-cut test, in each of the reference examples 1 to 3, the plating underlayer was not stripped away from the stainless steel plate. On the other hand, in each of the reference examples 4 and 5, the plating underlayer was stripped away from the stainless steel plate. As a result, it was confirmed that, in a case in which a woods bath was used as an electrolytic solution, adhesion of a plating underlayer was good.

On the other hand, it was confirmed that, in a case in which a watts bath was used as an electrolytic solution, adhesion of a plating underlayer was not good. It is considered that, this is because a passive film formed on the surface of a stainless steel plate cannot be removed in a case in which a watts bath is used as an electrolytic solution.

(2) Conductor Layer

In each of the following reference examples 6 to 12, a plating underlayer was formed on a conductor layer under various conditions by the plating apparatus 100, and evaluation was conducted.

In the comparative example 6, a copper-foil CF-T49A-DS-HD2-18 (manufactured by FUKUDA METAL FOIL & POWDER Co., LTD.) was used as a conductor layer. After the pre-process was executed similarly to the inventive example 1, the electrolytic plating process was executed. In the electrolytic plating process, a woods bath was used as an electrolytic solution. The current density in the electrolytic solution was 2 A/dm², and the temperature of the electrolytic solution was 25° C. The concentration of nickel chloride in the electrolytic solution was 240 g/L, and the concentration of hydrochloric acid was 120 ml/L. A plating period of time was 60 seconds.

In the reference example 7, the pre-process and the electrolytic plating process were executed similarly to the reference example 6 except for the following points. In the electrolytic plating process, the electrolytic plating process was executed similarly to the above-mentioned reference example 6 except that the current density in the electrolytic solution was 15 A/dm², and a plating period of time was 30 seconds.

In the reference example 8, the pre-process and the electrolytic plating process were executed similarly to the reference example 7 except for the following points. In the electrolytic plating process, the current density in an electrolytic solution was 30 A/dm².

In the reference example 9, the pre-process and the electrolytic plating process were executed similarly to the reference example 6 except that a copper alloy foil HS1200 (manufactured by JX Nippon Mining & Metals Corporation) was used as a conductor layer.

In the comparative example 10, a copper foil CF-T49A-DS-HD2-18 (manufactured by FUKUDA METAL FOIL & POWDER Co., LTD.) was used as a conductor layer. After the pre-process was executed similarly to the reference example 1, the electrolytic plating process was executed. In the electrolytic plating process, a watts bath was used as an electrolytic solution. The current density in the electrolytic solution was 2 A/dm², and the temperature of the electrolytic solution was 55° C. The concentration of nickel chloride in the electrolytic solution was 64 g/L, the concentration of nickel sulfate was 260 g/L, and the concentration of boric acid was 33 ml/L. A plating period of time was 60 seconds.

In the reference example 11, the pre-process and the electrolytic plating process were executed similarly to the reference example 10 except for the following points. In the electrolytic plating process, the current density in the electrolytic solution was 4 A/dm², and a plating period of time was 30 seconds.

In the reference example 12, the pre-process and the electrolytic plating process were executed similarly to the reference example 10 except that a copper alloy foil HS1200 (manufactured by JX Nippon Mining & Metals Corporation) was used as a conductor layer.

The adhesion of the plating underlayers formed in the reference examples 6 to 12 was evaluated by a cross-cut test. Table 3 shows the plating conditions and the evaluation results in regard to adhesion of the plating underlayers in the reference examples 6 to 12.

TABLE 3

| | REFERENCE | REFERENCE | REFERENCE | REFERENCE | REFERENCE | REFERENCE | REFERENCE |
|---|---|---|---|---|---|---|---|
| | EXAMPLE | EXAMPLE | EXAMPLE | EXAMPLE | EXAMPLE | EXAMPLE | EXAMPLE |
| | 6 | 7 | 8 | 9 | 10 | 11 | 12 |
| ELECTROLYTIC | WOODS | WOODS | WOODS | WOODS | WATTS | WATTS | WATTS |
| SOLUTION | BATH | BATH | BATH | BATH | BATH | BATH | BATH |
| CONDUCTOR | COPPER | COPPER | COPPER | COPPER | COPPER | COPPER | COPPER |
| LAYER | | | | ALLOY | | | ALLOY |
| CURRENT | 2 | 15 | 30 | 2 | 2 | 4 | 2 |
| DENSITY [A/dm²] | | | | | | | |
| TEMPERATURE | 25 | 25 | 25 | 25 | 55 | 55 | 55 |
| OF | | | | | | | |
| ELECTROLYTIC | | | | | | | |
| SOLUTION [° C.] | | | | | | | |
| CONCENTRATION | 240 | 240 | 240 | 240 | 64 | 64 | 64 |
| OF NICKEL | | | | | | | |
| CHLORIDE[g/L] | | | | | | | |
| CONCENTRATION | 120 | 120 | 120 | 120 | | | |
| OF | | | | | | | |
| HYDROCHLORIC | | | | | | | |
| ACID[m/L] | | | | | | | |
| CONCENTRATION | | | | | 260 | 260 | 260 |
| OF NICKEL | | | | | | | |
| SULFATE[g/L] | | | | | | | |
| CONCENTRATION | | | | | 33 | 33 | 33 |
| OF BORIC ACID | | | | | | | |
| [g/L] | | | | | | | |
| PLATING PERIOD | 60 | 30 | 30 | 60 | 60 | 30 | 60 |
| OF TIME [seconds] | | | | | | | |
| EVALUATION | GOOD | GOOD | GOOD | GOOD | GOOD | GOOD | GOOD |

As shown in Table 3, as a result of the cross-cut test, in each of the reference examples 6 to 12, the plating underlayer was not stripped away from the conductor layer. As a result, it was confirmed that, in a case in which either of a woods bath and a watts bath was used as an electrolytic solution, adhesion of a plating underlayer was good. It is considered that, this is because a passive film is hardly formed on the surface of a conductor layer.

### [4] Method of Manufacturing Printed Circuit Board

(1) Configuration of Suspension Board

A method of manufacturing a printed circuit board according to embodiments of the present invention will be described. A printed circuit board in the following embodiments is a suspension board with a circuit (hereinafter abbreviated as suspension board) used for an actuator of a hard disc drive device.

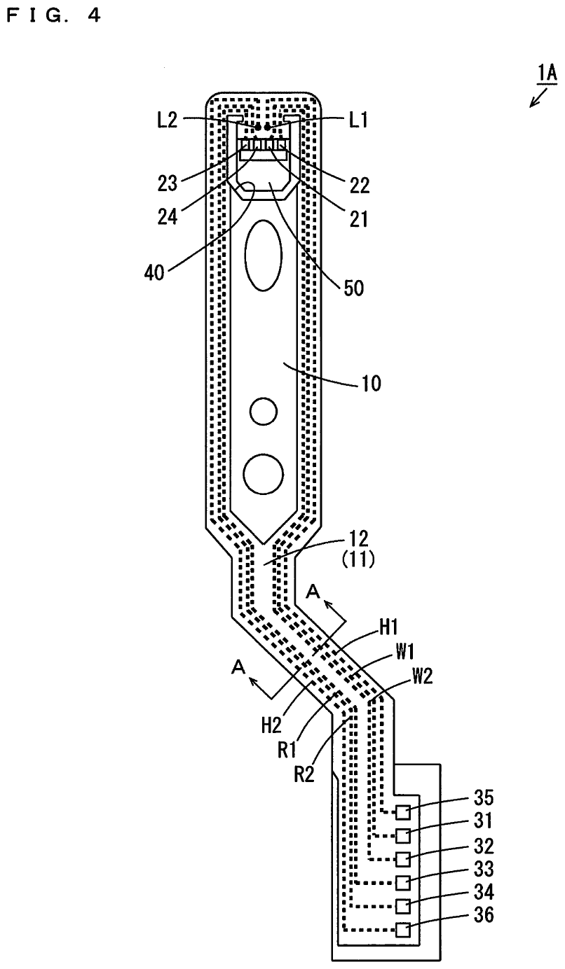

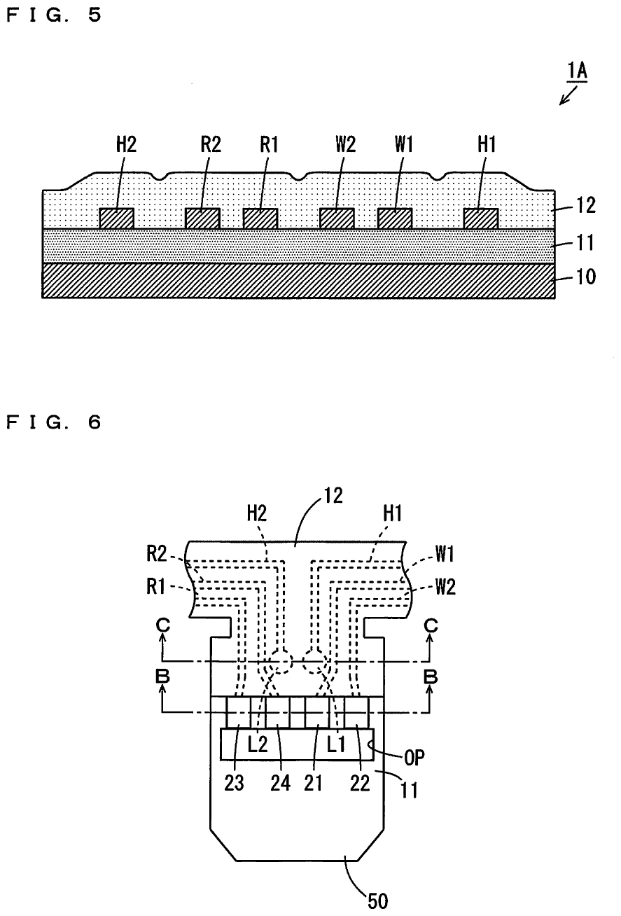

FIG. 4 is a plan view of a suspension board. FIG. 5 is a cross sectional view of the suspension board 1A of FIG. 4 taken along the line A-A. As shown in FIGS. 4 and 5, the suspension board 1A includes an elongated support substrate 10. The support substrate 10 is made of stainless steel.

A base insulating layer 11 made of polyimide, for example, is formed on the support substrate 10. Write wiring traces W1, W2, read wiring traces R1, R2 and heat-assisted wiring traces H1, H2 are formed on the base insulating layer 11. The write wiring traces W1, W2, the read wiring traces R1, R2 and the heat-assisted wiring traces H1, H2 are made of copper (Cu) or a copper alloy.

The write wiring traces W1, W2 and the heat-assisted wiring trace H1 are formed in a region extending along one side of the support substrate 10. The heat-assisted wiring trace H1 is arranged outwardly of the write wiring traces W1, W2. The read wiring traces R1, R2 and the heat-assisted wiring trace H2 are formed in a region extending along the other side of the support substrate 10. The heat-assisted wiring trace H2 is arranged outwardly of the read wiring traces R1, R2.

At one end of the support substrate 10, a magnetic head supporting portion (hereinafter referred to as a tongue) 50 is provided by formation of a U-shaped opening 40. One end of each of the write wiring traces W1, W2, the read wiring traces R1, R2 and the heat-assisted wiring traces H1, H2 extends on the tongue 50. On the tongue 50, a connection terminal 21 is provided at one end of the write wiring trace W1, and a connection terminal 22 is provided at one end of the write wiring trace W2. Further, a connection terminal 23 is provided at one end of the read wiring trace R1, and a connection terminal 24 is provided at one end of the read wiring trace R2.

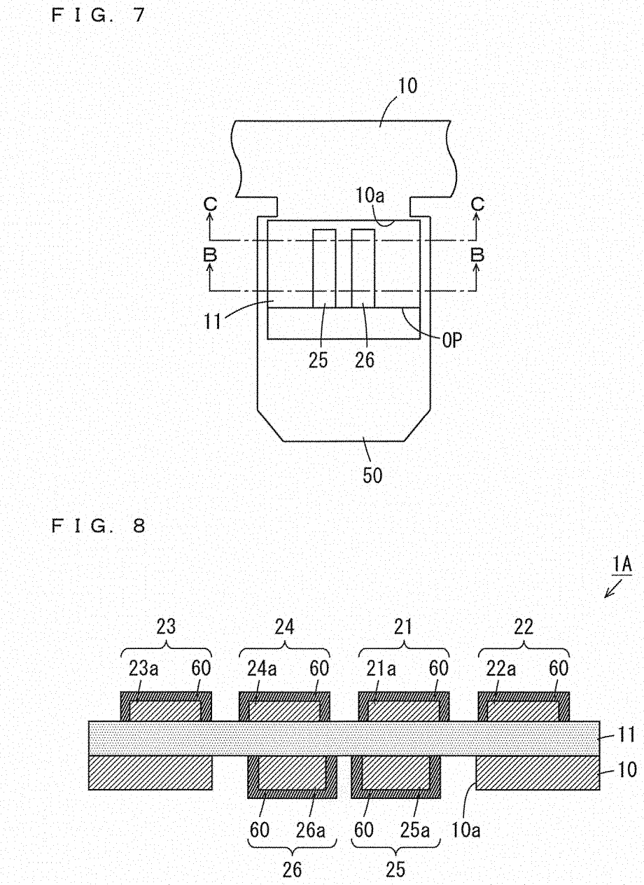

Further, on the tongue 50, a land portion L1 is provided at one end of the heat-assisted wiring trace H1, and a land portion L2 is provided at one end of the heat-assisted wiring trace H2. As described below, the land portions L1, L2 are connected to the connection terminals 25, 26 (FIG. 7), respectively.

On the other end of the support substrate 10, a connection terminal 31 is provided at the other end of the write wiring trace W1, and a connection terminal 32 is provided at the other end of the write wiring trace W2. Further, a connection terminal 33 is provided at the other end of the read wiring trace R1, and a connection terminal 34 is provided at the other end of the read wiring trace R2. Further, a connection terminal 35 is provided at the other end of the heat-assisted wiring trace H1, and a connection terminal 36 is provided at the other end of the heat-assisted wiring trace H2.

A cover insulating layer 12 made of polyimide, for example, is formed on the base insulating layer 11 to cover portions of the write wiring traces W1, W2, the read wiring traces R1, R2 and the heat-assisted wiring traces H1, H2 except for the connection terminals 21 to 24, 31 to 36. Under the cover insulating layer 12, a metal film made of nickel, for example, may be formed so as to cover each of the write wiring traces W1, W2, the read wiring traces R1, R2 and the heat-assisted wiring traces H1, H2.

(2) Tongue

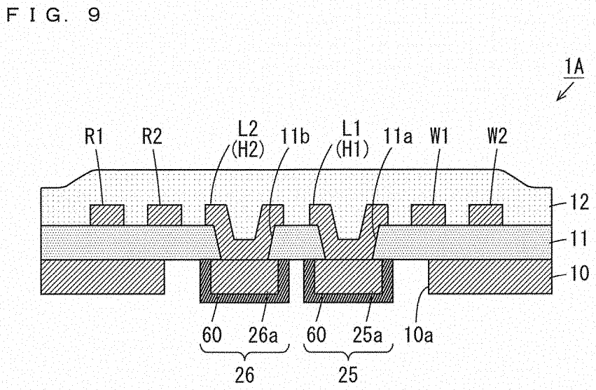

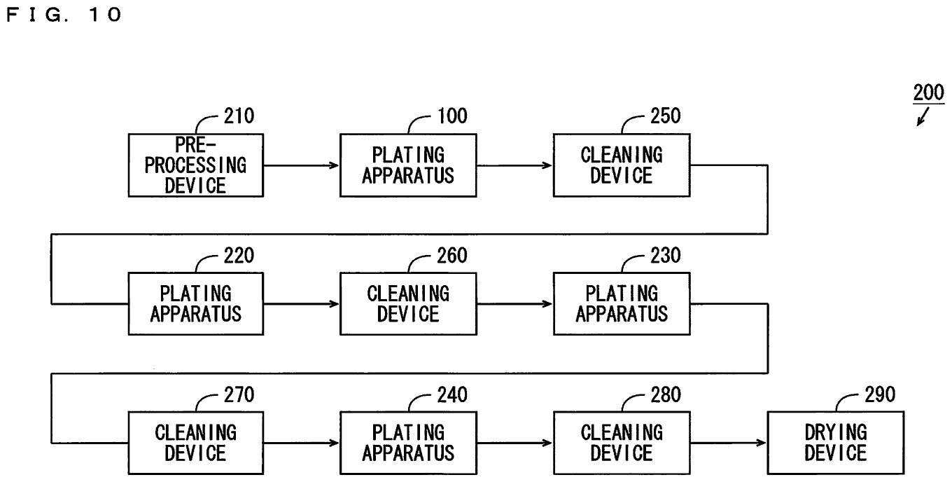

Details of the tongue 50 will be described. FIG. 6 is an enlarged plan view of the tongue 50 as viewed from one side (the same side as FIG. 4). FIG. 7 is an enlarged plan view of the tongue 50 as viewed from the other side (the opposite side to FIG. 4). FIG. 8 is a cross sectional view of the tongue 50 of each of FIGS. 6 and 7 taken along the line B-B. FIG. 9 is a cross sectional view of the tongue 50 of each of FIGS. 6 and 7 taken along the line C-C.

As shown in FIG. 6, the connection terminals 21 to 24 of the write wiring traces W1, W2 and the read wiring traces R1, R2 are not covered by the cover insulating layer 12. On the other hand, the land portions L1, L2 of the heat-assisted wiring traces H1, H2 are covered by the cover insulating layer 12. A rectangular opening OP is formed in the base insulating layer 11. The connection terminals 21 to 24 are arranged to extend along one side of the opening OP.

As shown in FIG. 7, an opening 10a is formed in the support substrate 10. The opening OP of the base insulating layer 11 overlaps with part of the opening 10a of the support substrate 10. In the opening 10a, the connection terminals 25, 26 are provided on the lower surface of the base insulating layer 11. One end of the connection terminal 25 overlaps with the land portion L1 of FIG. 6, and one end of the connection terminal 26 overlaps with the land portion L2 of FIG. 6. The other end of each of the connection terminals 25, 26 is arranged so as to be extend along the above-mentioned one side of the opening OP of the base insulating layer 11.

In the following description, the one end of the write wiring trace W1 is referred to as a terminal portion 21a, and the one end of the write wiring trace W2 is referred to as a terminal portion 22a. Similarly, the one end of the read wiring trace R1 is referred to as a terminal portion 23a, and the one end of the read wiring trace R2 is referred to as a terminal portion 24a. Further, portions of the support substrate 10 formed in the opening 10a of the support substrate 10 are referred to as terminal portions 25a, 26a. The terminal portions 25a, 26a are separated from the rest of the support substrate 10. As shown in FIG. 8, cover layers 60 made of a plurality of plating layers are formed so as to cover the side surfaces and the upper surface of each of the terminal portions 21a to 24a. Thus, the connection terminals 21 to 24 are formed.

As shown in FIG. 9, tapered holes 11a, 11 b are respectively formed in portions of the base insulating layer 11 on the one end of the terminal portion 25a and the one end of the terminal portion 26a. The land portion L1 is provided so as to come into contact with the upper surface of the base insulating layer 11, the inner peripheral surface of the hole 11a and the upper surface of the terminal portion 25a. The land portion L2 is provided so as to come into contact with the upper surface of the base insulating layer 11, the inner peripheral surface of the hole 11b and the upper surface of the terminal portion 26a. A cover layer 60 made of a plurality of plating layers is formed so as to cover the side surfaces and the lower surface of each of the terminal portions 25a, 26a. Thus, the connection terminals 25, 26 are formed.

A slider (not shown) including a magnetic head is attached to the upper surface of the tongue 50. Connection terminals of the slider are electrically connected to the connection terminals 21 to 24 of the write wiring traces W1, W2 and the read wiring traces R1, R2. A heat-assisted device such as a laser diode is attached to the lower surface of the slider so as to project from the lower surface of the tongue 50 through the opening OP of the base insulating layer 11 and the opening 10a of the support substrate 10. Connection terminals of the heat-assisted device are electrically connected to the connection terminals 25, 26. When information is written into a magnetic disc by the magnetic head, the magnetic disc is heated by the heat-assisted device. Thus, density of the information to be written into the magnetic disc can be improved.

(3) Plating System

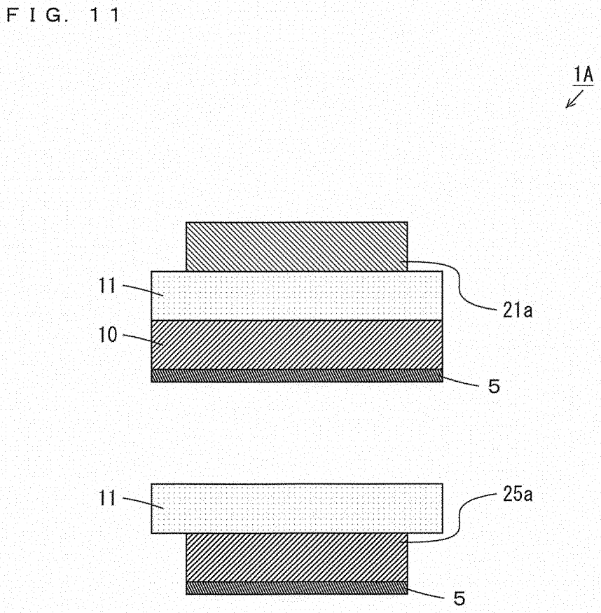

FIG. 10 is a block diagram showing the configuration of a plating system used in a method of manufacturing the suspension board 1A. As shown in FIG. 10, the plating system 200 includes the plating apparatus 100 of FIG. 1 and includes a pre-processing device 210, plating apparatuses 220, 230, 240, cleaning devices 250, 260, 270, 280 and a drying device 290. The pre-processing device 210 is provided at the most upstream position of the plating system 200 and executes a pre-process on the suspension board 1A. The pre-process includes degreasing and cleaning with acid.

The plating apparatuses 100, 220, 230, 240 are provided in this order from an upstream position to a downstream position. The plating apparatuses 220, 230, 240 basically have the configuration similar to that of the plating apparatus 100 except that an electrolytic liquid is different. The cover layer 60 of FIGS. 8 and 9 is constituted by plating layers sequentially formed by the plating apparatuses 100, 220, 230, 240.

The plating apparatus 100 executes an electrolytic plating process (hereinafter referred to as a strike plating process) using a relatively high current for a short period of time on a plated portion of the suspension board 1A on which the pre-process has been executed by the pre-processing device 210, thereby forming a thin plating underlayer made of nickel on the plated portion. The cleaning device 250 is provided between the plating apparatus 100 and the plating apparatus 220 and cleans the suspension board 1A on which the strike plating process has been executed by the plating apparatus 100 with water.

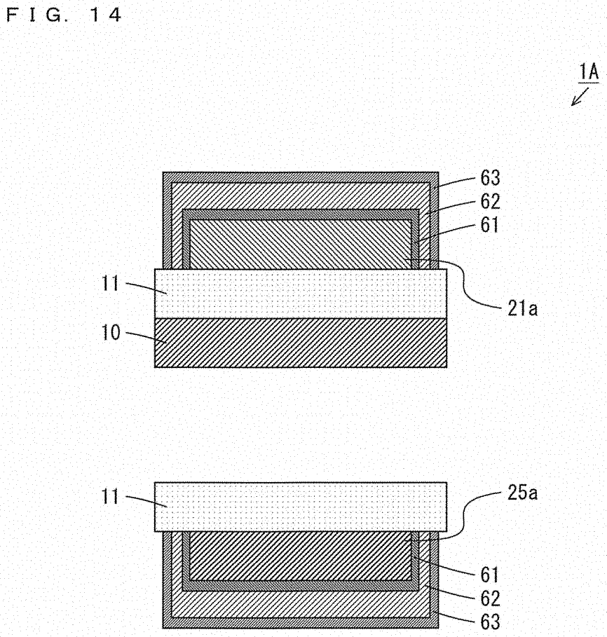

The plating apparatus 220 executes an electrolytic plating process (hereinafter referred to as a soft plating process) using a relatively low current on the plated portion of the suspension board 1A which has been cleaned by the cleaning device 250. In this case, a plating underlayer 62 of FIG. 13, described below, having a sufficiently large thickness can be formed. The cleaning device 260 is provided between the plating apparatus 220 and the plating apparatus 230 and cleans the suspension board 1A on which the soft plating process has been executed by the plating apparatus 220 with water.

The plating apparatus 230 executes the strike plating process for a short period of time on the plated portion of the suspension board 1A that has been cleaned by the cleaning device 260, thereby forming a thin main plating layer made of gold (Au) on the thick plating underlayer. The cleaning device 270 is provided between the plating apparatus 230 and the plating apparatus 240 and cleans the suspension board 1A on which the strike plating process has been executed by the plating apparatus 230 with water.

The plating apparatus 240 executes the soft plating process for a long period of time on the plated portion of the suspension board 1A that has been cleaned by the cleaning device 270, thereby forming a thick main plating layer made of gold (Au) on the thin main plating underlayer. Since the main plating layer is formed, corrosion resistance of the surface of the plated portion can be improved, and wettability of a solder can be improved. The cleaning device 280 is provided at a position farther downstream than the plating apparatus 240 and cleans the suspension board 1A on which the soft plating process has been executed by the plating apparatus 240 with water. The drying device 290 is provided at the most downstream position of the plating system 200 and dries the suspension board 1A that has been cleaned by the cleaning device 280.

(4) Method of Manufacturing Suspension Board

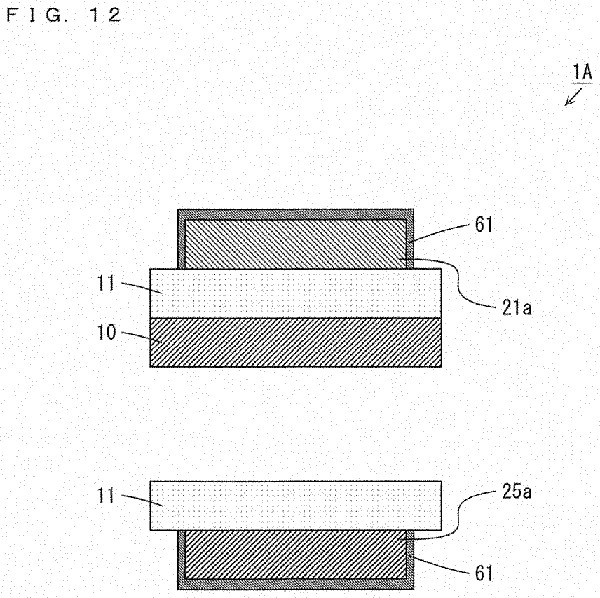

FIGS. 11 to 15 are cross sectional views for explaining the steps in the method of the manufacturing the suspension board 1A. In the upper fields of FIGS. 11 to 15, the steps of manufacturing the connection terminal 21 of FIG. 8 are shown. In the lower fields of FIGS. 11 to 15, the steps of manufacturing the connection terminal 25 of FIG. 8 are shown. The method of manufacturing the suspension board 1A will be described below with use of the plating system 200 of FIG. 10 and the cross sectional views for explaining the steps in FIGS. 11 to 15.

First, as shown in FIG. 11, the suspension board 1A is prepared as the laminate 1. In the suspension board 1A, the support substrate 10 and the terminal portions 25a, 26a, which are a stainless-steel plate, are formed on the lower surface of the base insulating layer 11. Further, the write wiring traces W1, W2, the read wiring traces R1, R2 and the heat-assisted wiring traces H1, H2 that are conductor layers are formed on the upper surface of the base insulating layer 11. In FIGS. 11 to 15, the terminal portions 22a to 24a, 26a, the write wiring traces W1, W2, the read wiring traces R1, R2, the heat-assisted wiring traces H1, H2 and the cover insulating layer 12 are not shown.

A plating resist layer (not shown) is formed on the surfaces of the stainless steel plate and the conductor layer excluding first and second plated portions. In the present example, the terminal portions 25a, 26a are the first plated portions. One end (terminal portions 21a to 24a) and the other end of each of the write wiring traces W1, W2 and the read wiring traces R1, R2 are the second plated portions.

The steps of manufacturing the connection terminals 22 to 24, 31 to 36 are similar to the steps of manufacturing the connection terminal 21. The steps of manufacturing the connection terminal 26 are similar to the steps of manufacturing the connection terminal 25. Therefore, in the following description, the connection terminals 22 to 24, 26, 31 to 36 will not be mentioned.

In the pre-processing device 210, a pre-process is executed on the suspension board 1A. Also in this case, as shown in FIG. 11, a firm passive film 5 formed on the surfaces of the support substrate 10 and the terminal portion 25a remains without being removed.

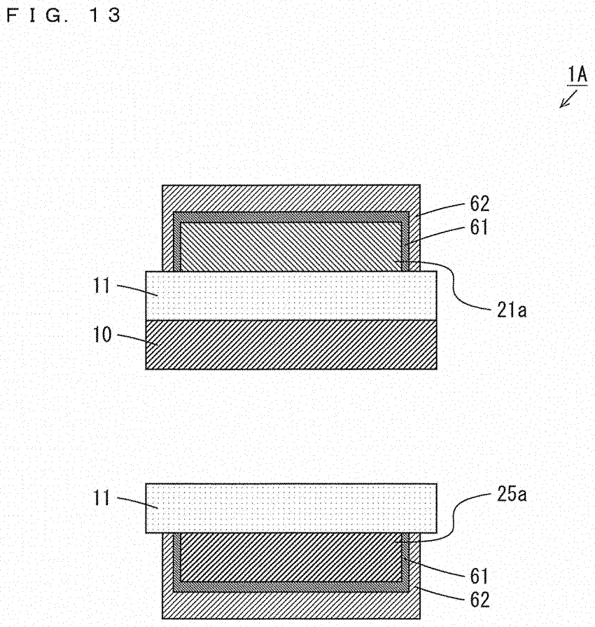

Next, as shown in FIG. 12, the strike plating process is executed on the plated portions of the suspension board 1A in the plating apparatus 100. Thus, a plating underlayer 61 made of nickel is formed so as to cover the side surfaces and the upper surface of the terminal portion 21a. Further, a plating underlayer 61 made of nickel is formed so as to cover the side surfaces and the lower surface of the terminal portion 25a. In this step, the passive films 5 formed on the support substrate 10 and the terminal portion 25a are removed by an electrolytic solution. After the plating underlayers 61 are formed, the suspension board 1A is cleaned in the cleaning device 250.

Subsequently, as shown in FIG. 13, the soft plating process is executed on the plated portions of the suspension board 1A in the plating apparatus 220. Thus, a plating underlayer 62 made of nickel is formed so as to cover the side surfaces and the upper surface of the plating underlayer 61 of the terminal portion 21a. Further, a plating underlayer 62 made of nickel is formed so as to cover the side surfaces and the lower surface of the plating underlayer 61 of the terminal portion 25a. The thickness of the plating underlayers 62 is larger than the thickness of the plating underlayers 61. The plating underlayers 62 may be formed on the terminal portion 21a and the terminal portion 25a at the same time under the same plating condition. After the plating underlayers 62 are formed, the suspension board 1A is cleaned in the cleaning device 260.

Thereafter, as shown in FIG. 14, the strike plating process is executed on the plated portions of the suspension board 1A in the plating apparatus 230. Thus, a main plating layer 63 made of gold (Au) is formed so as to cover the side surfaces and the upper surface of the plating underlayer 62 of the terminal portion 21a. Thus, a main plating layer 63 made of gold (Au) is formed so as to cover the side surfaces and the upper surface of the plating underlayer 62 of the terminal portion 25a. The main plating layers 63 may be formed on the terminal portion 21a and the terminal portion 25a at the same time under the same plating condition. After the main plating layers 63 are formed, the suspension board 1A is cleaned in the cleaning device 270.

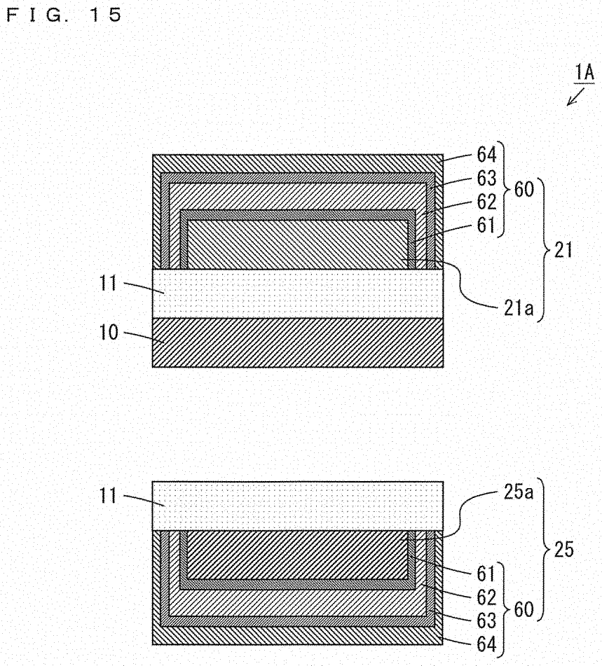

Subsequently, as shown in FIG. 15, the soft plating process is executed on the plated portions of the suspension board 1A in the plating apparatus 240. Thus, a main plating layer 64 made of gold (Au) is formed so as to cover the side surfaces and the upper surface of the main plating layer 63 of the terminal portion 21a. Thus, a main plating layer 64 made of gold (Au) is formed so as to cover the side surfaces and the lower surface of the main plating layer 63 of the terminal portion 25a. The main plating layers 64 may be formed on the terminal portion 21a and the terminal portion 25a at the same time under the same plating condition. The thickness of the main plating layers 64 is larger than the thickness of the main plating layers 63.

The connection terminal 21 is manufactured by formation of the cover layer 60 made of the plating underlayers 61, 62 and the main plating layers 63, 64 on the terminal portion 21a. Similarly, the connection terminal 25 is manufactured by formation of the cover layer 60 made of the plating underlayers 61, 62 and the main plating layers 63, 64 on the terminal portion 25a. Finally, the suspension board 1A is cleaned in the cleaning device 280, and the suspension board 1A is dried in the drying device 290. Thus, the suspension board 1A is completed.

(5) Effects

With the method of manufacturing the suspension board 1A according to the present embodiment, because a hydrochloric acid electrolytic solution is used, the plating underlayers 61 made of nickel are formed on the terminal portions 25a, 26a made of stainless steel and the terminal portions 21a to 24a and the like made of copper or a copper alloy at the same time. Thus, the connection terminals 25, 26 and the connection terminals 21 to 24, 31 to 36 are formed at the same time. In this case, an increase in number of steps required for manufacturing of the suspension board 1A is prevented. Therefore, the cost required for manufacturing of the suspension board 1A can be reduced more sufficiently.

The connection terminals 21 to 26, 31 to 36 are formed under the same plating condition. Specifically, the connection terminals 21 to 26, 31 to 36 are formed at the same current density (that is the same voltage). In this case, the plating process can be executed on the terminal portions 25a, 26a, the terminal portions 21a to 24a and the like in the same plating tank. Thus, the cost required for manufacturing of the suspension board 1A can be reduced more sufficiently. Further, this more sufficiently facilitates formation of the plating underlayers 61 on the terminal portions 25a, 26a, the terminal portions 21a to 24a and the like at the same time.

The connection terminals 21 to 26, 31 to 36 are formed by application of a voltage to each of the terminal portions 21a to 26a and the like with use of the common electrode 150. In this case, an increase in number of components required for manufacturing of the suspension board 1A is prevented. Thus, the cost required for manufacturing of the suspension board 1A can be reduced more sufficiently.

### [5] Other Embodiments

(1) While the plating method according to the present invention is used for manufacturing of the suspension board 1A for an actuator of a hard disc drive device in the above-mentioned embodiment, the embodiment is not limited to this. The plating method according to the present invention may be used for manufacturing of another electronic product, a circuit board or the like, and may be used for another laminate 1 constituted by stainless steel, and copper or a copper alloy.

(2) While the plating underlayer 62, the main plating layer 63 and the main plating layer 64 are formed on the plating underlayer 61 formed on a plated portion in the above-mentioned embodiment, the embodiment is not limited to this. Part or all of the plating underlayer 62, the main plating layer 63 and the main plating layer 64 does not have to be formed.

(3) While the plating underlayers are formed on the first plated portion and the second plated portion under the same condition in the above-mentioned embodiment, the embodiment is not limited to this. The plating underlayers may be formed on the first plated portion and the second plated portion under different plating conditions. For example, the plating underlayers may be formed on the first plated portion and the second plated portion at different current densities or different voltages.

(4) While the plating underlayers are formed by application of a voltage to each of the first plated portion and the second plated portion with use of the common electrode 150 in the above-mentioned embodiment, the embodiment is not limited to this. The plating underlayers may be formed by application of a voltage to each of the first plated portion and the second plated portion with use of separately provided electrodes 150. In this case, one electrode 150 may be arranged to be opposite to the stainless steel plate 2, and the other electrode 150 may be arranged to be opposite to the conductor layer 4.

### [6] Correspondences Between Constituent Elements in Claims and Parts in Preferred Embodiments

In the following paragraphs, non-limiting examples of correspondences between various elements recited in the claims below and those described above with respect to various preferred embodiments of the present disclosure are explained.

In the above-mentioned embodiment, the stainless steel plate 2 is an example of stainless steel, the conductor layer 4 is an example of copper, a copper alloy or a conductor layer, and the laminate 1 is an example of a laminate. The terminal portions 25a, 26a are an example of a first plated portion or a first terminal portion, the terminal portions 21a to 24a are an example of a second plated portion or a second terminal portion, and the plating underlayers 61, 62 are an example of a plating underlayer. The electrode 150 is an example of an electrode, the main plating layers 63, 64 are an example of a plating layer, the suspension board 1A is an example of a printed circuit board, the connection terminals 25, 26 are an example of a first connection terminal, and the connection terminals 21 to 24, 31 to 36 are an example of a second connection terminal.

While preferred embodiments of the present disclosure have been described above, it is to be understood that variations and modifications will be apparent to those skilled in the art without departing the scope and spirit of the present disclosure. The scope of the present disclosure, therefore, is to be determined solely by the following claims.

I/We claim:

1. A plating method including:
preparing a laminate made of stainless steel, and copper or a copper alloy; and
forming plating underlayers made of nickel on a first plated portion provided at the stainless steel and a second plated portion provided at the copper or the copper alloy at a same time using a hydrochloric acid electrolytic solution.

2. The plating method according to claim 1, wherein
the forming plating underlayers includes forming plating underlayers on the first plated portion and the second plated portion under a same plating condition.

3. The plating method according to claim 2, wherein
the plating condition includes a current density or a voltage.

4. The plating method according to claim 1, wherein
the forming plating underlayers includes applying a voltage to each of the first plated portion and the second plated portion using a common electrode.

5. The plating method according to claim 1, wherein
a concentration of hydrochloric acid in an electrolytic solution is not less than 60 ml/L.

6. The plating method according to claim 1, further including forming plating underlayers made of nickel on plating underlayers formed on the first plated portion and the second plated portion.

7. The plating method according to claim 1, further including forming plating layers made of gold (Au) on plating underlayers formed on the first plated portion and the second plated portion.

8. The plating method according to claim 1, wherein
the laminate is a printed circuit board in which the stainless steel and a conductor layer made of copper or a copper alloy are laminated,
the first plate portion is a first terminal portion provided at the stainless steel, and
the second plated portion is a second terminal portion provided at the conductor layer.

9. A method of manufacturing a printed circuit board including:
preparing a laminate including stainless steel and a conductor layer made of copper or a copper alloy;
forming a first connection terminal and a second connection terminal at the laminate at a same time;
forming the first connection terminal includes forming a plating underlayer made of nickel on a first terminal portion provided at the stainless steel using a hydrochloric acid electrolytic solution; and
forming the second connection terminal includes forming a plating underlayer made of nickel on a second terminal portion provided at the conductor layer using a hydrochloric acid electrolytic solution.

10. The method of manufacturing a printed circuit board according to claim 9, wherein
the forming a first connection terminal and a second connection terminal includes forming the first connection terminal and the second connection terminal under a same plating condition.

11. The method of manufacturing a printed circuit board according to claim 10, wherein
the plating condition includes a current density or a voltage.

12. The method of manufacturing a printed circuit board according to claim 9, wherein
the forming a first connection terminal and a second connection terminal includes applying a voltage to each of the first terminal portion and the second terminal portion using a common electrode.

13. The method of manufacturing a printed circuit board according to claim 9, wherein
a concentration of hydrochloric acid in an electrolytic solution is not less than 60 ml/L.

14. The method of manufacturing a printed circuit board according to claim 9, wherein
the forming the first connection terminal further includes forming a plating underlayer made of nickel on a plating underlayer formed on the first terminal portion, and
the forming the second connection terminal further includes forming a plating underlayer made of nickel on a plating underlayer formed on the second terminal portion.

15. The method of manufacturing a printed circuit board according to claim 9, wherein
the forming the first connection terminal includes forming a plating layer made of gold (Au) on a plating underlayer formed on the first terminal portion, and
the forming the second connection terminal further includes forming a plating layer made of gold (Au) on a plating underlayer formed on the second terminal portion.
